(19) United States
(12) Patent Application Publication
(10) Pub. No.: US 2015/0309093 A1
(43) Pub. Date: Oct. 29, 2015

(54) METHOD FOR AUTOMATICALLY MEASURING POWER CONSUMPTION OF MOBILE DEVICE CORRESPONDING TO EXECUTING GIVEN EVENT

(71) Applicant: CHUNGJIN LEE, BASKING RIDGE, NJ (US)

(72) Inventor: CHUNGJIN LEE, BASKING RIDGE, NJ (US)

(21) Appl. No.: 14/691,731

(22) Filed: Apr. 21, 2015

Related U.S. Application Data
(60) Provisional application No. 61/983,646, filed on Apr. 24, 2014.

(51) Int. Cl. G01R 21/00

(52) U.S. Cl. CPC G01R 21/00

(57) ABSTRACT

A method to automatically measure power consumption of mobile devices corresponding to executing a given event is provided. The computing device instructs mobile devices to automatically execute a given event and collects data associated with power consumption, including current consumption measurements, from current meter. The computing device automatically selects the range of current consumption measurement data by predetermined time period or by pulse-shaped current consumption measurement. The computing device further measures power consumption by identifying ranges of all pulse-shaped current consumption measurements in a given time frame for mobile device to execute a given event and selecting the range having the highest average current consumption or the range generated at the time mobile device executes a given event.

### CROSS-REFERENCE TO RELATED APPLICATIONS

Provisional Application No. U.S. 61/983,646, filed on Apr. 24, 2014.

### Cross-Reference to Related Applications

This patent application claims the benefit of U.S. Provisional Patent Application No. 61/983,646, filed on Apr. 24, 2014, which is incorporated by reference.

### STATEMENT REGARDING FEDERALLY SPONSORED RESEARCH OR DEVELOPMENT

Not Applicable

### REFERENCE TO SEQUENCE LISTING, A TABLE, OR A COMPUTER PROGRAM LISTING COMPACT DISC APPENDIX

Not Applicable

### TECHNICAL FIELD OF THE INVENTION

The present invention relates to battery life testing of mobile devices and more particularly to methods for automatically measuring power consumption of mobile device corresponding to executing an event as instructed in a test case of battery life test.

### BACKGROUND OF THE INVENTION

Battery life has become an important consideration for users in selecting mobile device, such as smartphone, tablet PC, and smartwatch. Since modern mobile device offers more services, functions and features to users, i.g. call, SMS, email, gaming, navigation, video streaming, audio streaming and more, manufacturers and wireless service providers have increased their efforts in battery life testing to improve battery life of mobile device as well as providing accurate battery life estimate to consumers.

In battery life test, it is important to find the range of current consumption measurements as well as respective start and end point of such range that truly represents the current consumption of mobile device for executing an event as instructed in a test case. However, it has been challenging for human testers in manually select the precise range of current consumption measurements along with its respective star point and end point. Thus, conventional battery life test requires testers to conduct each test case of battery life test repetitively to ensure accuracy and reliability of current consumption measurements for calculating battery life. Therefore, it is desirable to have a method to automatically measure power consumption of mobile device corresponding to executing a given eve y automatically selecting the range of current drain measurement that truly represents the current consumption of mobile device for executing a given event.

### BRIEF SUMMARY OF THE INVENTION

In general, this disclosure is directed to methods for automatically measuring power consumption of mobile devices corresponding to executing given event. In one example, a system to implement the methods for automatically measuring power consumption of mobile devices corresponding to executing given event includes: mobile devices execute given events from a computing device; a power device supplies predetermined voltage to the mobile devices and measures current drain by each of the mobile devices; computing device collects power consumption related data from the power device and determines the range of power consumption related data of mobile devices corresponding to executing each of the given events.

In an example, the computing device includes instructions for causing a programmable processor: to transmit events to the mobile devices; to collect data associated with power consumption of the mobile devices from the power device; and to determine power consumption of the mobile devices corresponding to executing given event using time control logic, pulse-shaped detection algorithm and selection filter algorithm.

In an example, a method to measure power consumption of mobile devices corresponding to executing given events include the computer-executable instructions causing a programmable processor to select the measurement data within the predetermined time period using time control logic based on the requirement set forth in each test case of battery life test.

In an example, another method to measure power consumption of mobile devices corresponding to executing given events include the computer-executable instructions causing a programmable processor to identify all ranges of the power measurement data having pulse-shaped current consumption measurements in predetermined time frame for executing a given event and to select the range, amongst the identified ranges, having the highest average current consumption measurement or to select the range generated at the same time as when the mobile devices execute given events.

In an example, the method for identifying ranges of power measurement data having pulse-shaped current consumption measurements include the computer-executable instructions causing a programmable processor to determine rising point of each range within predetermined time frame for executing a given event by choosing the measurement sample having the degree of increase in current consumption between the sample and the following samples in a consecutive order exceeds the predetermined threshold level. The subsequent sample having equal or less current consumption measurement than the rising point may be the falling point of each range. Depending on sampling rate of current meter, the rising and falling points may be determined by using all measurement samples or measurement samples collected at predetermined time interval.

The details of one or more embodiments of the disclosure are found in the accompanying drawings and the detailed description of the invention below. Other advantages and objects of the present disclosure will be apparent from the description and drawings, and from the claims.

### BRIEF DESCRIPTION OF THE DRAWINGS

FIG. 1 illustrates an exemplary system to implement the method of the present invention to automatically measure power consumption of mobile devices corresponding to executing given event.

FIG. 2 shows flowchart for methods to identify and record ranges that include pulse-shaped current consumption measurements in a predetermined time frame for executing a given event that satisfies predetermined threshold value.

FIG. 3 is a block diagram depicting the method for automatically measure power consumption of mobile devices by selecting the range of current consumption measurements corresponding to executing given events.

### DETAILED DESCRIPTION OF THE INVENTION

It is to be understood that the described embodiments contained herein are merely illustrative of numerous and varied other embodiments which may constitute applications of the principles of the invention. Such other embodiments may be readily devised by those skilled in the art without departing from the spirit or scope of this invention and it is our intent they be deemed within the scope of our invention.

In conventional battery life test, testers manually choose the range of current consumption measurements to calculate power consumption corresponding to executing a given event. For instance, measuring current consumption of mobile device executing voice call or streaming video may include current consumption measurements for the entire duration of active call or video play. On the contrary, measuring current consumption of mobile device that sends or receives a text message may include current consumption measurements at the moment when the mobile device sends or receives a txt message which occurs within a few seconds. In the latter case of sending or receiving a text message, the measurement of current consumption by mobile device is pulse-shaped where current consumption by mobile device having steady current consumption suddenly spikes up followed by quick return to current consumption level before such increase. Since pulse-shaped measurements may be noise or interruption associated with battery life testing of mobile device connected to alive network, it is desirable to have a method that automatically measures power consumption of mobile device corresponding to executing a given event by selecting the range of pulse-shaped measurement that is not noise or interruption.

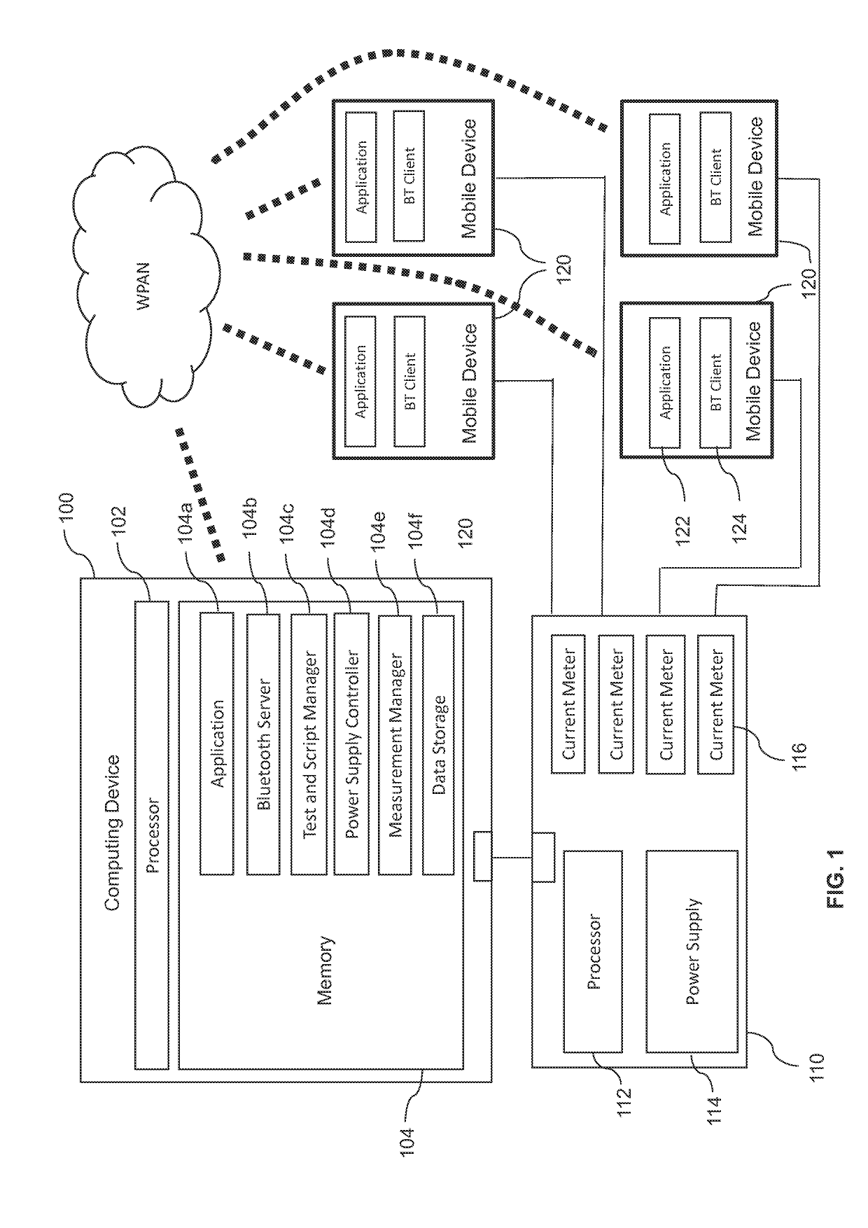

FIG. 1 illustrates an exemplary system to implement the method of the present invention to automatically measure power consumption of mobile devices corresponding to executing a given event. The exemplary system for implementing the method provided in the present invention may comprise a computing device 100 that configured to administer automated battery life test with automatic measurement methods; a power device 110 configured to supply power to mobile devise under test 120 and measures current consumption by each of mobile device under test 120; and mobile devices under test 120 configured to automatically execute the given events by the computing device 100.

In an embodiment, the computing device 100 may be implemented on a desktop computer, laptop computer or tablet computer. The computing device 100 may include processor 102 to execute computer executable instructions and memory 104 to store the said instructions. The memory 104 unit further includes the application unit 104a configured to manage user interface of the battery life test program; the Bluetooth server unit 104b configured to connect to each of the mobile devices under test 120; the test and script manager unit 104c configured to create manage a series of teas scripts that causes each mobile device under test 120 to automatically execute the given events; the power supply controller unit 104d configured to control the power device; the measurement manager unit 104e configured to automatically determine the power consumption of mobile device corresponding to executing a given event; and data storage 104f to store current consumption data associated with power consumption measurement.

In an embodiment, the power device 110 includes a processor 112 configured to transmit current consumption measurement data to the computing device 100; a power supply unit 114 configured to supply predetermined voltage to each mobile device under test 120; and current meters 116 to measure current drain of each mobile device under test 120. In an exemplary embodiment, 4 current meters are used to measure current consumption by 4 mobile devices.

In an embodiment, the mobile device under test 120 may be any mobile device such as smartphone, tablet PC or smart watches. For purpose of power consumption measurement, battery of mobile device is removed. Mobile devices under test 120 may be powered by the power device 110 through a dummy battery or a direct cable between the mobile devices and the power device 120. Each mobile device under test 120 includes application unit 122 to execute events as instructed by the computing device 100 and BT client unit 124 to connect each mobile device under test 120 to the computing device 100. When access to data network is required, mobile devices under test 120 may be configured to connect to live network which may include a private or public local area network (LAN), Wide Area Network (WANs), Global System for Mobile Communications (GSM), Code Division Multiple Access (CDMA), Enhanced Data for Global Evolution (EDGE) and other standard or proprietary wireless communication protocol.

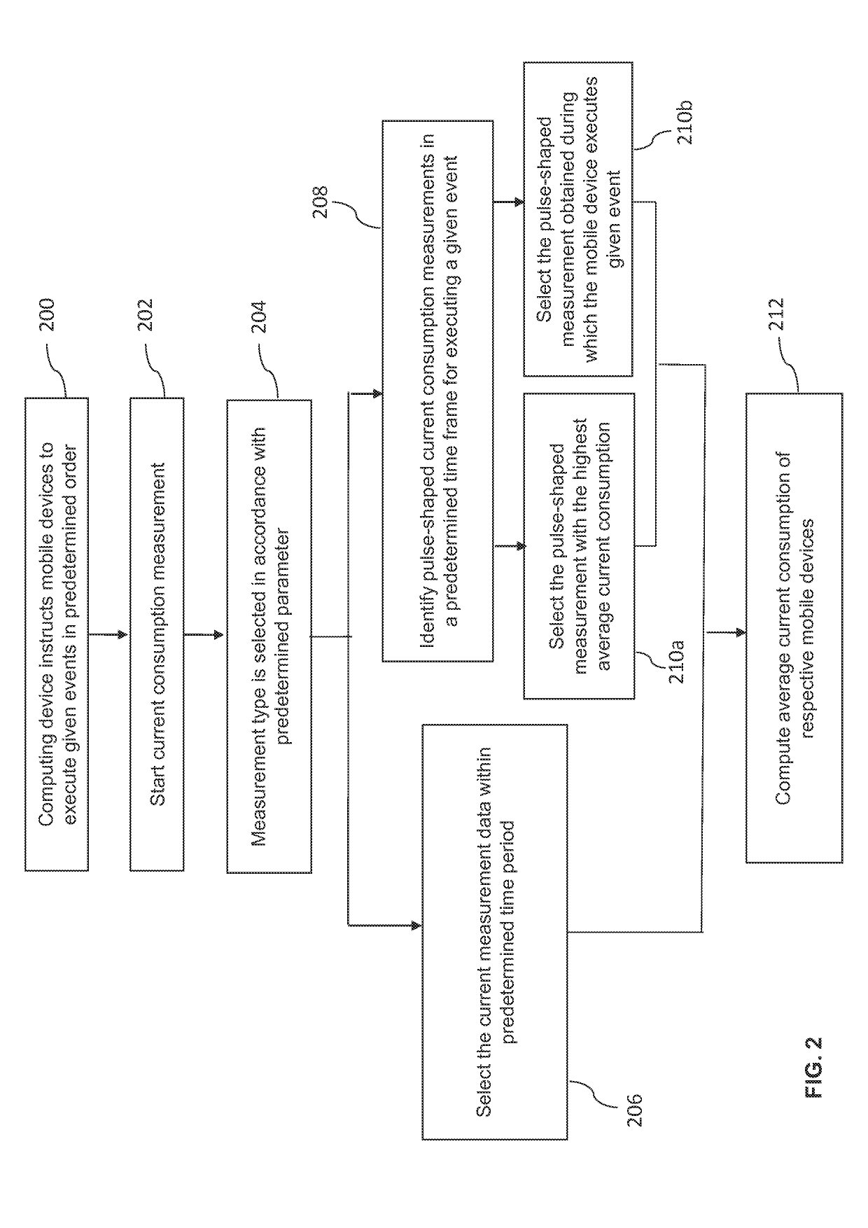

FIG. 2 is a block diagram illustrating methods to automatically measure power consumption of mobile devices corresponding to executing a given event. In an embodiment, a method for automatically measuring power consumption by mobile devices under test 120 may include: instructing, by computing device 100, mobile devices under test 120 to execute given event in predetermined order 200; rising current consumption measurement 202; selecting time based measurement type 204; selecting, by the measurement manager 104e, the current measurement data within predetermined time period when mobile device is executing a given event; and computing the average current consumption within the range of measurements 212.

The method for automatically measuring power consumption by mobile devices under test 120 may further include: instructing, by computing device 100, mobile devices under test 120 to execute given event in predetermined order 200; rising current consumption measurement 202; selecting the max or event based pulse-shaped measurement type 204; identifying all pulse-shaped current consumption measurements in a predetermined time frame for executing a given event 208; selecting the range of pulse-shaped current consumption measurements having the highest average current consumption in a predetermined time frame for executing a given event 210a or selecting the range of pulse-shaped current consumption measurements that was generated at the time mobile devices 120 execute a given event 210b; and computing the average current consumption within the range of measurements 212.

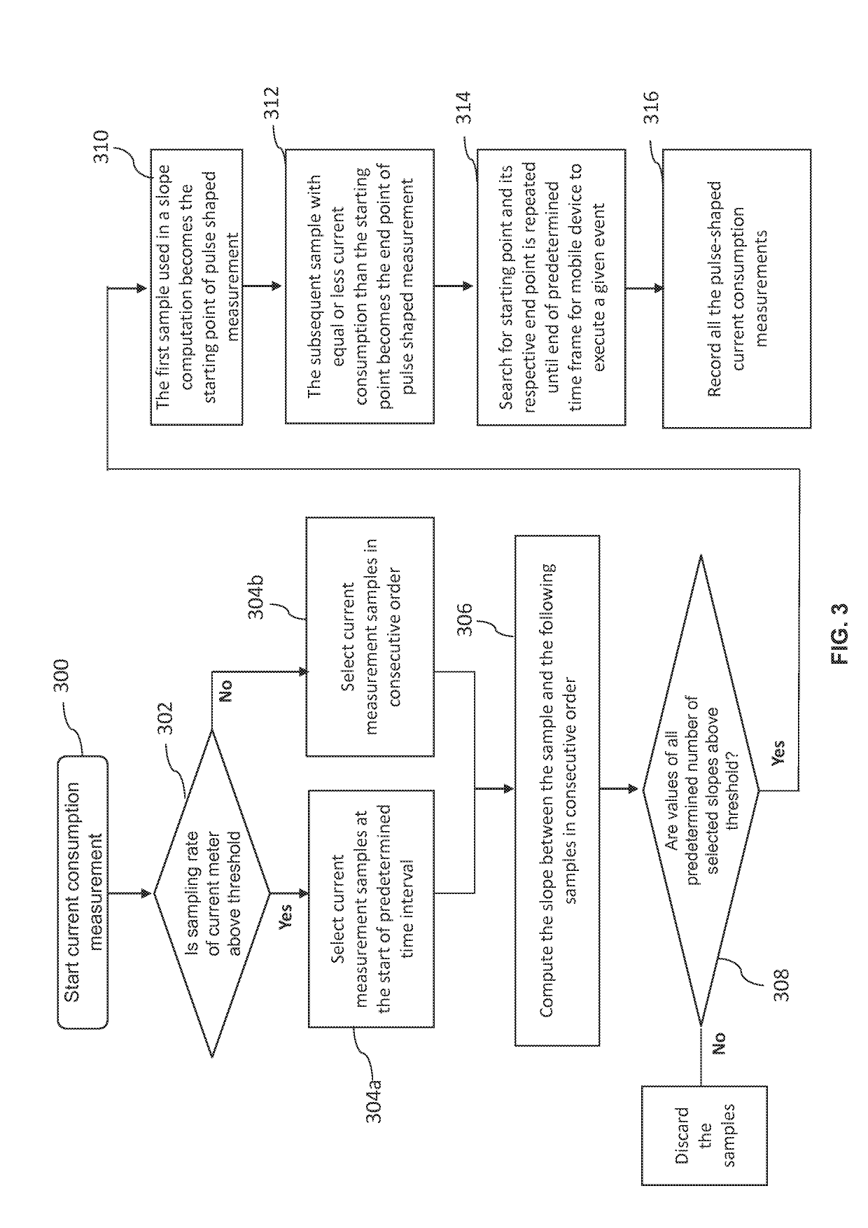

FIG. 3 is a flowchart illustrating method to find the pulse-shaped current consumption measurements in a predetermined time frame for mobile devices under test 120 to execute a given test event. The method for finding all pulse-shaped current consumption measurements in a predetermined time frame for mobile devices under test 120 includes: rising current consumption measurement of mobile devices under test 120 300; determining if sampling rate of current meter exceeds the predetermined threshold rate 302; selecting samples at the rising of each predetermined time interval when sampling rate exceeds the threshold 304a; selecting samples in consecutive order when sampling rate is below the threshold 304b; computing the slope between the sample and the following samples in consecutive order 306 wherein number of samples to compute slopes are predetermined; determining whether predetermined number of consecutive slopes exceed the predetermined threshold 308; selecting the first sample used in computing slopes that exceed the predetermined threshold as the rising point of a pulse-shaped current consumption measurement 310; selecting the subsequent sample having equal or less current consumption than the rising point as the falling point of a pulse-shaped current consumption measurement 312; repeating the selection of rising and falling point of pulse-shaped current consumption measurement unless a predetermined time frame for executing a given event is expired 314; and record all the pulse-shaped current consumption measurements identified with the rising and falling points 316 on the measurement manager 104e.

What is claimed is:

1. A method for automatically measuring power consumption of mobile devices corresponding to executing a given event under test case that requires measurement of current consumption in a predetermined time period, the method comprising: a computing device for selecting the range of current consumption measurements, the computing device having a non-transitory computer-readable medium with computer-executable instructions stored thereon, the computer-executable instructions comprising instructions for using time control logic to select the range of current consumption measurement based on predetermined time period within predetermined time frame for mobile devices to execute given event.

2. A method for automatically measuring power consumption of mobile devices corresponding to precise moment or time range when mobile devices execute a given event, the method comprising; a computing device for selecting the range of current consumption measurement, the computing device haying a non-transitory computer-readable medium with computer-executable instructions stored thereon, the computer-executable instructions comprising instructions for:
Identifying the ranges of all pulse-shaped current consumption measurements of mobile devices in a predetermined time frame for executing the event by determining the rising points and falling points of respective pulse-shaped current consumption measurements;
Selecting the range of pulse-shaped current consumption measurement having the highest average current consumption in a predetermined time frame for mobile devices to execute given event;
Selecting the range of pulsed-shaped current consumption measurement generated at the time mobile device executes a given event; and
Compute average current consumption in the selected range of pulse-shaped current consumption measurement to measure power consumption of mobile device corresponding to executing a given event.

3. The computing device of claim 2, wherein the computer-executable instructions for sample selection in determination of rising point and falling point of pulse-shaped current consumption measurements may include selecting samples at a predetermined time interval or selecting all consecutive samples.

4. The computing device of claim 2, wherein the computer-executable instructions for determining the rising points for ranges of pulse-shaped current consumption measurements include selecting number of samples be used in computation and computing the degree of increase in current consumption between the sample and the following samples in executive order.

5. The computing device of claim 2, wherein the computer-executable instructions for determining the falling points for ranges of pulse-shaped current consumption measurements include selecting the samples having equal or less current consumption than the respective sample at the rising point.
